(19) United States
(12) Patent Application Publication
(10) Pub. No.: US 2025/0253683 A1
(43) Pub. Date: Aug. 7, 2025

(54) ANALYSIS OF BATTERY CELLS DURING SWITCHED-MODE CONVERSION IN NORMAL OPERATION

(71) Applicant: Infineon Technologies Austria AG, Villach (AT)

(72) Inventors: Harald KOFFLER, Villach (AT); Giuseppe BERNACCHIA, Villach (AT)

(21) Appl. No.: 18/430,380

(22) Filed: Feb. 1, 2024

(51) Int. Cl. H02J 7/00; G01R 31/389; G01R 31/392

(52) U.S. Cl. CPC H02J 7/0029; G01R 31/389; G01R 31/392; H02J 7/005; H02J 2207/20

(57) ABSTRACT

A battery charging and discharging system includes a protection circuit and a control system. The protection circuit is configured to protect a charge/discharge circuit and is coupled between a battery terminal of at least one battery cell and a supply terminal. The supply terminal is configured to supply the charge/discharge circuit. Additionally, the protection circuit includes a protection transistor configured to receive a control signal and conduct a current based on the control signal. The control system is configured to modulate the control signal for controlling the protection transistor and for applying a perturbation to the current. Additionally, the control system is configured to measure an alternating current (AC) impedance of the at least one battery cell based on the perturbation being applied to the current.

### BACKGROUND

Many modern devices in automotive, consumer, and industrial applications, such as driving an electric motor or an electric machine, are becoming more reliant on power supplied by a battery pack of individual battery cells. A battery charging and discharging system may be used to discharge power from the battery pack to deliver power to a load, and may be used to recharge the battery pack. For example, a switched-mode power supply (SMPS) is a type of power supply that uses semiconductor switching techniques to provide a desired output voltage. The SMPS may include a power switching stage and a control circuit. The power switching stage may perform a power conversion to convert an input voltage to an output voltage and to generate an output current that may be used as a load current. For example, the power switching stage may include a transistor (e.g., a power switch) for performing the power conversion. The input voltage can be a direct current (DC) voltage provided from a DC supply, such as a battery pack. The control circuit may control a switching state of the transistor to regulate the power conversion. For example, the control circuit may control the transistor to switch between an ON state and an OFF state according to a duty cycle in order to regulate the output voltage to achieve the desired output voltage.

A converter topology of the SMPS, along with the switching scheme of the transistor implemented by the control circuit, dictates the power conversion. Possible converter topologies include a buck converter topology, a boost converter topology, a buck-boost converter topology (e.g., including a flyback converter topology and a hybrid flyback converter topology), and a boost power factor correction (PFC) converter topology. Other converter topologies also may be used. Additionally, the converter topology may include a single stage or two or more stages.

Some converter topologies may be coupled to a battery pack and used as a discharge circuit, while other converter topologies may be coupled to a battery pack and used as a charge/discharge circuit. For example, a buck-boost converter is a type of DC-to-DC converter that may be used as a charge/discharge circuit.

### SUMMARY

In some implementations, a battery charging and discharging system includes a protection circuit configured to protect a charge/discharge circuit and coupled between a battery terminal of at least one battery cell and a supply terminal, wherein the supply terminal is configured to supply the charge/discharge circuit, wherein the protection circuit includes a protection transistor configured to receive a first control signal and conduct a current based on the first control signal; and a first control system configured to modulate the first control signal for controlling the protection transistor and for applying a first perturbation to the current, wherein the first control system is configured to measure an alternating current (AC) impedance of the at least one battery cell based on the first perturbation being applied to the current.

In some implementations, a battery charging and discharging system includes a protection circuit configured to protect a charge/discharge circuit and coupled between a battery terminal of at least one battery cell and a supply terminal, wherein the battery terminal is configured to provide a battery supply voltage, wherein the supply terminal is configured to supply the charge/discharge circuit, wherein the protection circuit includes a protection transistor configured to receive a first control signal and conduct a current based on the first control signal, and a sink transistor coupled to a current-path terminal of the protection transistor and ground, and wherein the sink transistor is configured to receive a second control signal and sink a portion of the current based on the second control signal; and a control system configured to regulate the first control signal for controlling the protection transistor, and regulate the second control signal for controlling the sink transistor and for applying a perturbation to the current, wherein the control system is configured to measure a response of the battery supply voltage based on the perturbation being applied to the current, and determine at least one parameter value of the at least one battery cell based on the response.

In some implementations, a method of evaluating at least one battery cell includes controlling, by a control system, a protection transistor coupled between a battery terminal of the at least one battery cell and a supply terminal of a charge/discharge circuit, wherein the protection transistor is configured to conduct a current based on a control signal; modulating, by the control system, the control signal in order to apply a perturbation to the current; and measuring, by the control system, an AC impedance of the at least one battery cell based on the perturbation being applied to the current.

### BRIEF DESCRIPTION OF THE DRAWINGS

Implementations are described herein making reference to the appended drawings.

FIG. 1 illustrates a schematic block diagram of a battery charging and discharging system according to one or more implementations.

FIG. 2 shows a diagram of various examples of a perturbation according to one or more implications.

FIG. 3 illustrates a schematic block diagram of a battery charging and discharging system according to one or more implementations.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view, rather than in detail, in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually interchangeable.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling (e.g., any connection or coupling without additional intervening elements) may also be implemented by an indirect connection or coupling (e.g., a connection or coupling with one or more additional intervening elements, or vice versa) as long as the general purpose of the connection or coupling (e.g., to transmit a certain kind of signal or to transmit a certain kind of information) is essentially maintained. Features from different implementations may be combined to form further implementations. For example, variations or modifications described with respect to one of the implementations may also be applicable to other implementations unless noted to the contrary.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, a signal with an approximate signal value may practically have a signal value within 5% of the approximate signal value.

In the present disclosure, expressions including ordinal numbers, such as “first”, “second”, and/or the like, may modify various elements. However, such elements are not limited by such expressions. For example, such expressions do not limit the sequence and/or importance of the elements. Instead, such expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

A transistor typically comprises a semiconductor structure configured to conduct a load current along a load current-path between two load terminal structures of the transistor. Further, the load current may be controlled by a control electrode, sometimes referred to as a gate electrode, of the transistor. For example, upon receiving a corresponding control signal from, for example, a gate driver, the control electrode may set its transistor in one of a conducting state or a blocking state. Accordingly, the semiconductor structure behaves like a switch with ON and OFF states (i.e., conducting and blocking states, respectively). A transistor can be referred to as a power switch or a transistor switch that may be used in an SMPS to convert an input voltage into an output voltage.

Impedance measurements can be used to monitor and control a degradation of a battery performance during cycling. An impedance Nyquist plot may provide insight into several phenomena relative to a specific battery chemistry. However, the impedance Nyquist plot may change with temperature, rest time, and general operating conditions. Methodologies used to estimate parameters of a battery pack, such as a lithium-ion battery pack, include a current interrupt (CIR) method, an AC resistance method, a high-frequency resistance (HFR) method, and an electrochemical impedance spectroscopy (EIS) method.

During the CIR method, a current is interrupted for a very short interval (e.g., a few milliseconds) and a resulting dynamic response in voltage is recorded, which provides information on cell-internal parameters, that can be extracted from signal-processing said response in the domains of time and frequency.

During the AC resistance method, a fixed, single frequency sine wave (e.g., 1 kHz) is applied to the battery pack to measure a total impedance of the battery pack at a frequency of the single frequency sine wave.

During the HFR method, an electrolyte resistance is determined by applying a small AC signal to an electronic load to modulate a DC load current. A magnitude and a phase of an AC voltage and current response are measured by a frequency response analyzer. The HFR method uses a single frequency to evaluate the impedance.

During the EIS method, a small, sinusoidal perturbation at one or several frequencies is applied, and a response is an AC signal of a same frequency with a possible phase shift and amplitude change. While the EIS method may use more than one frequency, frequencies of the sinusoidal perturbation typically range from extremely low 10-2 Hz up to 105 Hz. For example, a frequency range below 1 kHz has been used to estimate a state of charge and a temperature of the battery pack. Moreover, an amplitude of the sinusoidal perturbation with EIS has been small, reaching around 10 mV per battery cell. The EIS method may be applied through two modes, including a galvanostatic mode and a potentiostatic mode. During the galvanostatic mode, a transfer function for an equivalent impedance of a battery cell is deduced from an evaluation of an AC voltage across the battery cell while applying a small AC current through the battery cell. During the potentiostatic mode, an AC voltage is applied to stimulate the battery cell, and a resulting AC current response is measured. The galvanostatic mode is generally preferred over the potentiostatic mode, because it is easier to apply a well-defined AC current than a well-defined AC voltage, to battery-cells which are strong voltage-sources themselves.

The EIS method may be implemented by modulating a duty cycle of a charge/discharge DC-to-DC converter (e.g., by modulating a duty cycle of a transistor of the charge/discharge DC-to-DC converter). However, implementing the EIS method in this manner is dependent on the operating point of the transistor. Moreover, an excitation frequency of the sinusoidal perturbation should be limited to a maximum about 10% of a switching frequency (e.g., a pulse width modulation (PWM) frequency) of the transistor, not to jeopardize its active operation under high-level control. Thus, the excitation frequency is dependent on the switching frequency. For example, the excitation frequency should be limited to about 10% of the switching frequency in order to avoid interference with control loops that control an active duty cycle in an SMPS of battery-electric systems, in order not to jeopardize a basic functionality or stability of the SMPS. For example, for a switching frequency of 10 kHz, the excitation frequency of the sinusoidal perturbation may be limited to a frequency range from 0 to 1 kHz such that the sinusoidal perturbation does not interfere with a primary switching operation of the transistor. Moreover, diagnostic functions on battery cells cannot be performed while a switched-mode conversion of voltage or power is active in normal operation. Instead, an analysis of the battery cells in general is being performed during quiescent periods, but not during normal-mode switched conversion. In other words, the sinusoidal perturbation may be stimulated at very low frequencies for diagnostic purposes during silent periods, during which switched-mode conversion is suspended, in order to avoid misleading interferences. Moreover, EIS may be performed while charging the battery, but not during discharging of the battery in operation, due to a higher signal-to-noise ratio that occurs during battery discharge by SMPS in operation.

Some implementations described herein combine diagnostic functionalities of battery-cells with switched-mode conversion into one comprehensive system to enable continuous monitoring of vital battery parameters while switched-mode conversion is ongoing and active.

Some implementations described herein may modulate diagnostic frequency-bands directly from a frequency-generation that is arranged in front of loops used for switched-mode power conversion, such that the frequency-generation does not interfere with ongoing control of a duty-cycle of a charge/discharge DC-to-DC converter.

Some implementations described herein may apply one or more excitation frequencies that are independent of a switching frequency of a charge/discharge DC-to-DC converter. Thus, much higher frequencies may be used for the one or more excitation frequencies. As a result of applying higher frequencies, subtle parameters of the battery cells may be measured, which would not be measurable at lower frequencies (e.g., at frequencies lower than 1 kHz). For example, one or more excitation frequencies may be in a MHz-range of 1 MHz or greater.

Some implementations described herein may enable applications of switched-mode power converters to stimulate additional frequency-bands for diagnosis of battery cells with minimum effort, concurrently while converting voltage, current, and/or power.

Some implementations described herein may include a protection circuit configured to protect a charge/discharge circuit and configured with built-in battery diagnostic functionality. Thus, the protection circuit may provide protective functions integrated with a battery charging and discharging system. The protection circuit may be coupled between a battery terminal of at least one battery cell and a supply terminal of the charge/discharge circuit.

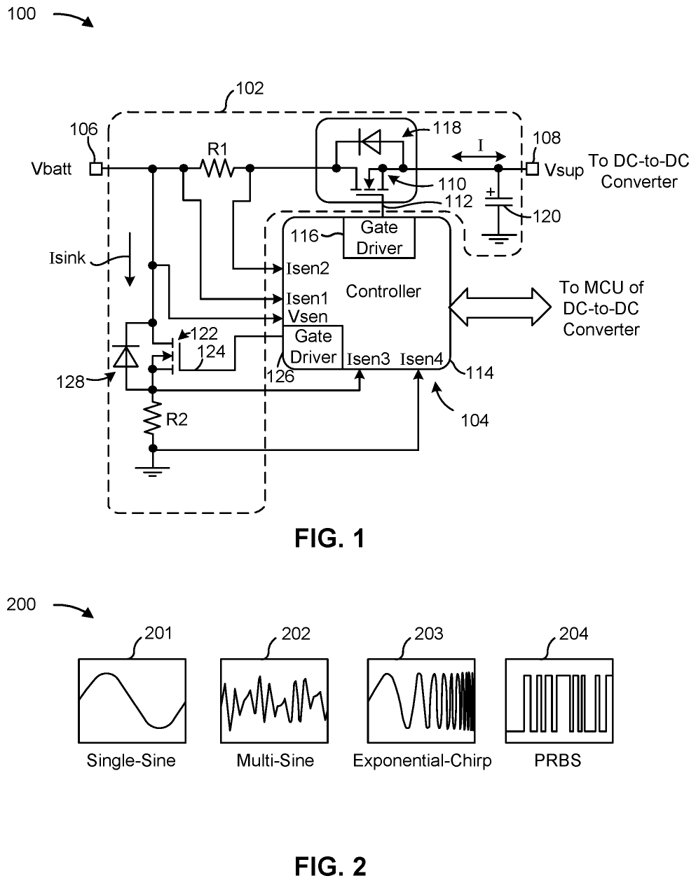

FIG. 1 is one example of a battery charging and discharging system 100, with the protection circuit, schematic block diagram of a battery charging and discharging system 100 according to one or more implementations. The battery charging and discharging system 100 may include a protection circuit 102 and a control system 104 (e.g., a first control system 104). The protection circuit 102 may be coupled between a battery terminal 106 of at least one battery cell and a supply terminal 108. The battery terminal 106 may be a terminal of a battery or a battery pack that includes the at least one battery cell. The battery terminal may provide a battery supply voltage Vbatt. The supply terminal 108 may be configured to supply a charge/discharge circuit, such as an SMPS. For example, a DC-to-DC converter of an SMPS may be coupled to the supply terminal 108. The supply terminal 108 may provide a converter supply voltage Vsup to the charge/discharge circuit. The charge/discharge circuit may use the converter supply voltage Vsup as an input voltage and convert the input voltage at the supply terminal 108 to an output voltage Vout that may be provided to a load.

The protection circuit 102 may be configured to protect the charge/discharge circuit. For example, the protection circuit 102 may include a protection transistor 110 configured to receive a first control signal 112 from the control system 104 and conduct a current I between the battery terminal 106 and the supply terminal 108 based on the first control signal 112. The protection transistor 110 may include a first current-path terminal coupled to the battery terminal 106, and a second current-path terminal coupled to the supply terminal 108. When configured in a conduction state, the protection transistor 110 may conduct the current I between the first current-path terminal and the second current-path terminal.

During a fault event, the control system 104 may control the protection transistor 110 to disconnect the charge/discharge circuit from the battery terminal 106. For example, the control system 104 may include a controller 114 (e.g., a digital controller) and a gate driver 116. The controller 114 may control the gate driver 116 to generate the first control signal 112 that is provided to a control electrode of the protection transistor 110. In some implementations, the gate driver 116 may be integrated with the controller 114. In some implementations, the controller 114 may be communicatively coupled with a microcontroller unit (MCU) of the charge/discharge circuit.

In addition, the protection circuit 102 may include an anti-parallel diode 118 (e.g., a freewheeling diode) that is coupled to the two current-path terminals of the protection transistor 110. The anti-parallel diode 118 may allow a reverse current flow from the supply terminal 108 to the battery terminal 106. In some implementations, the anti-parallel diode 118 may be co-packaged or otherwise integrated with the protection transistor 110.

The control system 104 may be configured to modulate the first control signal 112 for controlling the protection transistor 110 and for applying a first perturbation to the current I. The first perturbation may be applied to the current I while the current I is a charging current or while the current I is a discharging current. As a charging current, the current I may flow from the supply terminal 108 to the battery terminal 106 for charging the battery. As a discharging current, the current I may flow from battery terminal 106 to the supply terminal 108 for discharging the battery and for supplying the charge/discharge circuit. The charge/discharge circuit may control a direction of a flow of the current I between the supply terminal 108 and the battery terminal 106. For example, during a charging operation, the charge/discharge circuit may provide the current I from the supply terminal 108 to the battery terminal 106 as the charging current for charging the at least one battery cell. During a discharging operation, the charge/discharge circuit may receive the current I at the supply terminal 108 from the battery terminal 106 as the discharging current for discharging the at least one battery cell.

The protection transistor 110 may inject the first perturbation onto the current I to convert the current I into an AC-modulated current having an excitation frequency of the first perturbation. The AC-modulated current may be used to analyze one or more battery parameters of the battery. In some implementations, the AC-modulated current may be a single sine wave, a combination of multiple sine waves, a frequency ramp, an exponential chirp (e.g., an exponential frequency chirp), or a pseudorandom binary sequence (PRBS). In some implementations, the AC-modulated current may have a multi-frequency profile comprising multiple frequencies, with each frequency being independent of the switching frequency of the charge/discharge circuit.

Moreover, the first perturbation may have an excitation frequency that is independent of a switching frequency of the charge/discharge circuit. For example, the excitation frequency may be independent of a switching frequency of one or more transistors or power switches used in a DC-to-DC converter of the charge/discharge circuit. For example, the control system 104 may modulate the first control signal to generate the first perturbation with the excitation frequency that is independent of the switching frequency of at least one power switch. As a result, the excitation frequency of the first perturbation may not be limited by the switching frequency. For example, the excitation frequency may not be limited to 10% or less of the switching frequency. A frequency profile of the AC-modulated current may match a frequency profile of the first perturbation. Thus, the AC-modulated current may include one or more frequencies that are greater than 10% of the switching frequency, one or more frequencies greater than 20% of the switching frequency, and so forth. In some implementations, the excitation frequency may include one or more frequencies equal to or greater than the switching frequency. In some implementations, the excitation frequency may include one or more frequencies in the MHz range.

The protection circuit 102 may include a decoupling capacitor 120 coupled to the supply terminal 108 and ground. The decoupling capacitor 120 may reduce signal components of the first perturbation entering the charge/discharge circuit. For example, the decoupling capacitor 120 may be configured to filter out the first perturbation from the current I.

Additionally, the control system 104 may measure an AC impedance of the at least one battery cell based on the first perturbation being applied to the current I. For example, a resistor R1 may be provided in a current-path of the current I for measuring the AC-modulated current. The controller 114 may be configured to measure the AC-modulated current by measuring a voltage drop across the resistor R1 and calculating the AC-modulated current according to Ohm's Law using a known resistance value of the resistor R1. For example, the controller 114 may include a first sense terminal Isen1 and a second sense terminal Isen2 that are coupled across the resistor R1 for measuring the voltage drop across the resistor R1. The controller 114 may acquire a plurality of samples of the AC-modulated current to obtain a signal profile of the AC-modulated current. In addition, the controller 114 may include a battery sense terminal Vsen for measuring the battery supply voltage Vbatt at the battery terminal 106. Thus, the battery sense terminal Vsen may be used to obtain a direct measure of the battery supply voltage Vbatt. In some implementations, the first sense terminal Isen1 may be used to obtain the direct measure of the battery supply voltage Vbatt.

The controller 114 may measure an amplitude and a phase delay of the battery supply voltage Vbatt in response to the first perturbation being applied to the current I, and calculate the AC impedance based on the amplitude and the phase delay of the battery supply voltage Vbatt. For example, the controller 114 may measure the amplitude of the battery supply voltage Vbatt using the battery sense terminal Vsen. The phase delay may be a phase difference between the AC-modulated current and the battery supply voltage Vbatt. Thus, the controller 114 may measure the AC-modulated current using the first sense terminal Isen1 and the second sense terminal Isen2, and may determine the phase delay between the AC-modulated current and the battery supply voltage Vbatt.

In some implementations, the controller 114 may determine a state-of-health (SoH) parameter of the at least one battery cell based on the AC impedance. For example, the controller 114 may be part of a battery management system (BMS) that is configured with a battery model that is specific to a chemistry of the battery. The battery model may be stored in a memory of the controller 114 or in a memory device coupled to the controller 114. The battery model may be used by the controller 114 to calculate a state of charge (SoC) and/or the SoH of the battery using the measured AC impedance. For example, the controller 114 may use the battery module to relate different sections of the measured AC impedance to internal operational principles (e.g., chemical reactions) of the battery. The battery model and the measured AC impedance may be used by the controller 114 to calculate other battery parameters, such as cell impedance, temperature, presence of solid electrolyte interface, dendrite formation, and/or health of electrolyte. In addition, when the AC-modulated current has a multi-frequency profile comprising multiple frequencies, the controller 114 may measure the AC impedance of the at least one battery cell for each frequency of the multiple frequencies. For example, the controller 114 may measure the amplitude and the phase delay of the battery supply voltage Vbatt relative to each frequency (e.g., relative to each frequency component of the AC-modulated current). Thus, the controller 114 may apply a Fourier analysis to measure each frequency component or signal component of the AC-modulated current and the battery supply voltage Vbatt, and calculate the phase difference for corresponding frequency components or signal components for determining the AC impedance for each frequency. The controller 114 may calculate one or more battery parameters for each AC impedance using the battery model.

In some implementations, the control system 104 may apply the first perturbation to the current during a charging operation according to an EIS scheme (e.g., an EIS method). Thus, controller 114 may evaluate a response of the battery supply voltage Vbatt relative to the AC-modulated current based on the first perturbation injected onto the current I. The controller 114 may determine the AC impedance based on the EIS scheme (e.g., based on a function of the EIS scheme).

In some implementations, the protection circuit 102 may include a sink transistor 122 coupled to a current-path terminal of the protection transistor 110 and ground. The example provided in FIG. 1 shows that the sink transistor 122 is coupled to the battery terminal 106, and, therefore, coupled to the first current-path terminal of the protection transistor 110. However, in an alternative example, the sink transistor 122 may be coupled to the supply terminal 108, and, therefore, may be coupled to the second current-path terminal of the protection transistor 110. Thus, the sink transistor 122 may be coupled to a current-path of the current I, either upstream or downstream from the protection transistor 110.

The sink transistor 122 may receive a second control signal 124 from the control system 104 and sink a portion of the current I based on the second control signal 124. The control system 104 may include a gate driver 126 configured to generate the second control signal 124 and provide the second control signal 124 to a control electrode of the sink transistor 122. The controller 114 may control the gate driver 126 to generate the second control signal 124. In some implementations, the gate driver 126 may be integrated with the controller 114.

In addition, the protection circuit 102 may include an anti-parallel diode 128 (e.g., a freewheeling diode) that is coupled to two current-path terminals of the sink transistor 122. The anti-parallel diode 128 may allow a reverse current flow. In some implementations, the anti-parallel diode 128 may be co-packaged or otherwise integrated with the sink transistor 122.

The controller 114 may modulate the second control signal 124 for controlling the sink transistor 122 and for applying a second perturbation to the current I. The controller 114 may measure a response of the battery supply voltage Vbatt based on the second perturbation being applied to the current I, and determine a parameter value of the at least one battery cell, such as SoH, SoC, cell impedance, temperature, presence of solid electrolyte interface, dendrite formation, and/or health of electrolyte, based on the response.

For example, a resistor R2 may be provided in a current-path of the sink transistor 122 for measuring a sinked current Isink. The controller 114 may be configured to measure the sinked current Isink by measuring a voltage drop across the resistor R2 and calculating the sinked current Isink according to Ohm's Law using a known resistance value of the resistor R2. For example, the controller 114 may include a third sense terminal Isen3 and a fourth sense terminal Isen4 that are coupled across the resistor R2 for measuring the voltage drop across the resistor R2. The controller 114 may acquire a plurality of samples of the sinked current Isink to obtain a signal profile of the sinked current Isink. In addition, the controller 114 may include a battery sense terminal Vsen for measuring the battery supply voltage Vbatt at the battery terminal 106. Thus, the battery sense terminal Vsen may be used to obtain a direct measure of the battery supply voltage Vbatt for evaluating the response of the battery supply voltage Vbatt.

In some implementations, the second perturbation may be applied as a current step resulting in a decaying voltage waveform of the battery supply voltage Vbatt. The controller 114 may measure the response of the battery supply voltage Vbatt by measuring a time constant of the decaying voltage waveform of the battery supply voltage Vbatt. The time constant may be a duration required for the battery supply voltage Vbatt to reach a predefined percentage of an initial value. In other words, the time constant may be a measure of how quickly the battery supply voltage Vbatt reaches a steady state in response to the second perturbation.

In some implementations, the controller 114 may apply the second perturbation to the current I during a discharging operation of the charge/discharge circuit according to a CIR scheme (e.g., a CIR method). For example, the controller 114 may determine one or more parameter values based on the CIR scheme, such as amplitude and phase in complex impedance. Accordingly, the controller 114 may be configured to evaluate one of more battery parameters during a charging operation by applying the first perturbation via modulating the first control signal 112, and may be configured to evaluate one of more battery parameters during a discharging operation by applying the second perturbation via modulating the second control signal 124. Moreover, the second perturbation may be applied independently of the switching frequency of the charge/discharge circuit.

The control system 104 may include a scheduler for EIS or CIR interrupt, current profiles for one or more perturbations, one or more analog-to-digital converters (ADCs) for sampling voltages and/or currents, an AC impedance calculator, and/or a communication interface for synchronization with the MCU (e.g., start and stop synchronization).

As indicated above, FIG. 1 is provided as an example. Other examples may differ from what is described with regard to FIG. 1. The number and arrangement of components shown in FIG. 1 are provided as an example. In practice, the battery charging and discharging system 100 may include additional components, fewer components, different components, or differently arranged components than those shown in FIG. 1. Two or more components shown in FIG. 1 may be implemented within a single component, or a single component shown in FIG. 1 may be implemented as multiple, distributed components. Additionally, or alternatively, a set of components (e.g., one or more components) of the battery charging and discharging system 100 may perform one or more functions described as being performed by another set of components of the battery charging and discharging system 100.

FIG. 2 shows some example perturbations according to one or more implications. For example, the perturbation may correspond to the first perturbation applied by modulating an on/off state of the protection transistor 110. The first perturbation may be a single sine wave 201, a multi-sine wave 202 (e.g., a combination of multiple sine waves), an exponential chirp 203, or a PRBS 204.

As indicated above, FIG. 2 is provided as an example. Other examples may differ from what is described with regard to FIG. 2.

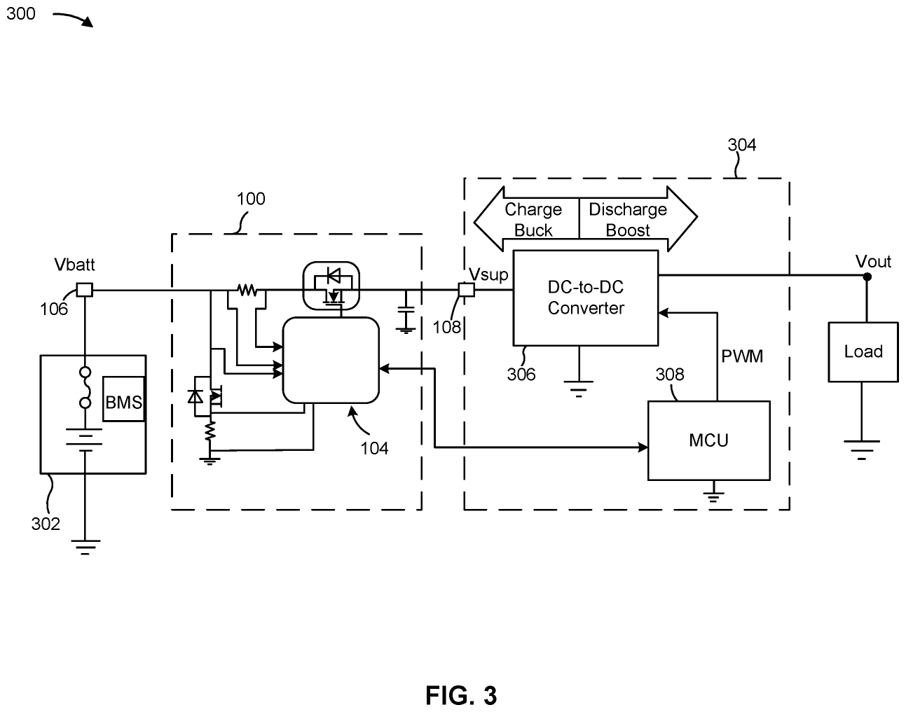

FIG. 3 shows an example with both the battery and the charge/discharge circuit connected to the protection circuit. Thus, FIG. 3 provides an example of a possible implementation. The invention is not limited to this example, a schematic block diagram of a battery charging and discharging system 300 according to one or more implementations. The battery charging and discharging system 300 may include the battery charging and discharging system 100 as described in connection with FIG. 1. In addition, the battery charging and discharging system 300 may include a battery 302, such as a battery pack, and a charge/discharge circuit 304, such as an SMPS. In some implementations, the battery charging and discharging system 100 including the protection circuit 102 and the first control system 104 may be integrated with the charge/discharge circuit 304.

The charge/discharge circuit 304 may include a DC-to-DC converter 306 coupled to the supply terminal 108. The DC-to-DC converter 306 may include at least one power switch and may be configured to use the at least one power switch to convert the converter supply voltage Vsup (e.g., the input voltage) at the supply terminal 108 to an output voltage Vout provided to a load. Additionally, the DC-to-DC converter 306 may control a flow of the current I between the supply terminal 108 and the battery terminal 106. The charge/discharge circuit 304 may further include a second control system 308 that is configured to regulate one or more PWM control signals for controlling the at least one power switch of the DC-to-DC converter 306. Each PWM control signal may be used to control a switching state and a switching frequency of a respective power switch of the DC-to-DC converter 306. The second control system 308 may include a controller, such as an MCU.

Additionally, the DC-to-DC converter 306 may include one or more diodes, one or more resistors, one or more inductors, and/or one or more capacitors based on a converter topology of the DC-to-DC converter 306. For example, the DC-to-DC converter 306 may be a single-switch buck-boost converter or a two-switch buck-boost converter. Thus, the DC-to-DC converter 306 may be a charge/discharge DC-to-DC converter. Additionally, the DC-to-DC converter 306 may include one or more gate drivers for driving the switching state of each power switch. For example, the DC-to-DC converter 306 may include a gate driver that receives one or more PWM control signals from the second control system 308, and generates a gate control signal for each power switch based on a respective PWM control signal.

The charge/discharge circuit 304 may control a direction of a flow of the current I between the supply terminal 108 and the battery terminal 106. For example, during a charging operation, the charge/discharge circuit 304 may provide the current I from the supply terminal 108 to the battery terminal 106 as a charging current for charging the at least one battery cell of the battery 302. Conversely, during a discharging operation, the charge/discharge circuit 304 may receive the current I at the supply terminal 108 from the battery terminal 106 as a discharging current for discharging the at least one battery cell of the battery 302. The second control system 308 may control a charging and a discharging of the at least one battery cell.

In some implementations, the first control system 104 and the second control system 308 may be communicatively coupled. For example, the controller 114 associated with the protection circuit 102 may be communicatively coupled to the MCU of the second control system 308. The MCU of the second control system 308 may control a timing at which the first control system 104 (e.g., the controller 114) is to apply the first perturbation and/or the second perturbation to the current I.

Additionally, or alternatively, the first control system 104 (e.g., the controller 114) may indicate, to the MCU of the second control system 308, a timing at which the first control system is to apply the first perturbation and/or the second perturbation to the current I. The MCU of the second control system 308 may compensate for the first perturbation and/or the second perturbation based on the timing of the first perturbation and/or the second perturbation, respectively.

By implementing an impedance measurement in a protection circuit of the battery charging and discharging system 300, the impedance measurement can be completely independent from the switching frequency of the DC-to-DC converter 306. Therefore, a range of frequencies used for the impedance measurement can be much larger than a range of frequencies that could be used when applying a perturbation within DC-to-DC converter 306. In addition, any current-modulation shape can be applied with the first perturbation. In contrast, a shape of a perturbation applied by duty cycle modulation within the DC-to-DC converter 306 is limited.

Moreover, the protection circuit 102 may operate in a quasi-static mode. Therefore, injecting the first perturbation with different shapes (e.g., single sine, a combination of sine waves, chirp signals, etc.) is much more feasible than applying different shapes with duty cycle modulation within the DC-to-DC converter 306.

Moreover, by using the sink transistor 122, a CIR method can be implemented while the battery is being discharged. The sink transistor 122 can apply a current step, to which the battery 302 responds with a decaying voltage waveform. The decaying voltage waveform may be measured and used to check a status of the battery 302. Since the decaying voltage waveform is a single point measurement in an impedance plot, the decaying voltage waveform may provide an indication about a shift of an impedance curve due to temperature drift or internal processes. The CIR method may not be practical to be implemented in the DC-to-DC converter 306 due to delays introduced by magnetic components of the DC-to-DC converter 306.

The protection transistor 110 and the sink transistor 122 may be used independently of each other or together (e.g., simultaneously). In other words, the first perturbation and the second perturbation may be applied to the current I separately (e.g., at different, exclusive time intervals) or in combination (e.g., at a same time).

A measurement of the AC impedance may be performed by measuring the perturbation and the response of the battery (Vbatt). If digitized, a discrete Fourier transform (DFT), such as a fast Fourier transform (FFT), can be applied to the measured perturbation and the measured Vbatt to obtain the AC impedance of the battery 302. Simpler algorithms can be applied if the perturbation is simple. For example, an amplitude of the voltage sine wave of Vbatt and the delay between the voltage peak of Vbatt and the current peak of the current I may be measured to determine the phase delay.

As indicated above, FIG. 3 is provided as an example. Other examples may differ from what is described with regard to FIG. 3.

The following provides an overview of some Aspects of the present disclosure:

Aspect 1: A battery charging and discharging system, comprising: a protection circuit configured to protect a charge/discharge circuit and coupled between a battery terminal of at least one battery cell and a supply terminal, wherein the supply terminal is configured to supply the charge/discharge circuit, wherein the protection circuit includes a protection transistor configured to receive a first control signal and conduct a current based on the first control signal; and a first control system configured to modulate the first control signal for controlling the protection transistor and for applying a first perturbation to the current, wherein the first control system is configured to measure an AC impedance of the at least one battery cell based on the first perturbation being applied to the current.

Aspect 2: The battery charging and discharging system of Aspect 1, wherein battery terminal is configured to provide a battery supply voltage, and wherein the first control system is configured to measure an amplitude and a phase delay of the battery supply voltage in response to the first perturbation being applied to the current, and calculate the AC impedance based on the amplitude and the phase delay of the battery supply voltage.

Aspect 3: The battery charging and discharging system of Aspect 2, wherein the protection transistor is configured to inject the first perturbation onto the current to convert the current into an AC-modulated current, and wherein the phase delay is a phase difference between the AC-modulated current and the battery supply voltage.

Aspect 4: The battery charging and discharging system of any of Aspects 1-3, wherein the first control system is configured to determine a state-of-health parameter of the at least one battery cell based on the AC impedance.

Aspect 5: The battery charging and discharging system of any of Aspects 1-4, wherein the protection transistor includes a first current-path terminal coupled to the battery terminal, and a second current-path terminal coupled to the supply terminal, and wherein the protection transistor is configured to inject the first perturbation onto the current to convert the current into an AC-modulated current having an excitation frequency that is independent of a switching frequency of the charge/discharge circuit.

Aspect 6: The battery charging and discharging system of Aspect 5, wherein the AC-modulated current has a multi-frequency profile comprising multiple frequencies, and wherein the first control system is configured to measure the AC impedance of the at least one battery cell for each frequency of the multiple frequencies.

Aspect 7: The battery charging and discharging system of Aspect 5, wherein the AC-modulated current is a single sine wave, a combination of multiple sine waves, a frequency ramp, an exponential chirp, or a pseudorandom binary sequence.

Aspect 8: The battery charging and discharging system of any of Aspects 1-7, wherein the protection circuit includes a decoupling capacitor coupled to the supply terminal and ground, and wherein the decoupling capacitor is configured to reduce signal components of the first perturbation entering the charge/discharge circuit.

Aspect 9: The battery charging and discharging system of any of Aspects 1-8, wherein the charge/discharge circuit is configured to control a direction of a flow of the current between the supply terminal and the battery terminal, and wherein, during a charging operation, the charge/discharge circuit is configured to provide the current from the supply terminal to the battery terminal as a charging current for charging the at least one battery cell, and wherein, during a discharging operation, the charge/discharge circuit is configured to receive the current at the supply terminal from the battery terminal as a discharging current for discharging the at least one battery cell.

Aspect 10: The battery charging and discharging system of Aspect 9, wherein the first control system is configured to apply the first perturbation to the current during the charging operation according to an EIS scheme, and wherein the first control system is configured to determine the AC impedance based on the EIS scheme.

Aspect 11: The battery charging and discharging system of any of Aspects 1-10, wherein the charge/discharge circuit comprises a second control system configured to control a charging and a discharging of the at least one battery cell, wherein the first control system and the second control system are communicatively coupled, and wherein the second control system is configured to control a timing at which the first control system is to apply the first perturbation to the current.

Aspect 12: The battery charging and discharging system of any of Aspects 1-11, wherein the charge/discharge circuit comprises a second control system configured to control a charging and a discharging of the at least one battery cell, wherein the first control system and the second control system are communicatively coupled, wherein the first control system is configured to indicate, to the second control system, a timing at which the first control system is to apply the first perturbation to the current, and wherein the second control system is configured to compensate for the first perturbation based on the timing.

Aspect 13: The battery charging and discharging system of any of Aspects 1-12, wherein battery terminal is configured to provide a battery supply voltage, wherein the protection circuit includes a sink transistor coupled to a current-path terminal of the protection transistor and ground, wherein the sink transistor is configured to receive a second control signal and sink a portion of the current based on the second control signal, wherein the first control system is configured to modulate the second control signal for controlling the sink transistor and for applying a second perturbation to the current, and wherein the first control system is configured to measure a response of the battery supply voltage based on the second perturbation being applied to the current, and determine a parameter value of the at least one battery cell based on the response.

Aspect 14: The battery charging and discharging system of Aspect 13, wherein the second perturbation is a current step resulting in a decaying voltage waveform of the battery supply voltage, and wherein the first control system is configured to measure the response of the battery supply voltage by measuring a time constant of the decaying voltage waveform of the battery supply voltage.

Aspect 15: The battery charging and discharging system of Aspect 13, wherein the first control system is configured to apply the second perturbation to the current during a discharging operation of the charge/discharge circuit according to a CIR scheme, wherein, during the discharging operation, the charge/discharge circuit is configured to receive the current at the supply terminal from the battery terminal as a discharging current for discharging the at least one battery cell, and wherein the first control system is configured to determine the parameter value based on the CIR scheme.

Aspect 16: The battery charging and discharging system of any of Aspects 1-15, wherein the charge/discharge circuit comprises: a DC-to-DC converter coupled to the supply terminal, wherein the DC-to-DC converter comprises at least one power switch and is configured to use the at least one power switch to convert an input voltage at the supply terminal to an output voltage and control a flow of the current between the supply terminal and the battery terminal; and a second control system configured to regulate at least one PWM control signal for controlling the at least one power switch.

Aspect 17: The battery charging and discharging system of Aspect 16, wherein the first control system is configured to modulate the first control signal to generate the first perturbation with an excitation frequency that is independent of a switching frequency of the at least one power switch.

Aspect 18: A battery charging and discharging system, comprising: a protection circuit configured to protect a charge/discharge circuit and coupled between a battery terminal of at least one battery cell and a supply terminal, wherein the battery terminal is configured to provide a battery supply voltage, wherein the supply terminal is configured to supply the charge/discharge circuit, wherein the protection circuit includes a protection transistor configured to receive a first control signal and conduct a current based on the first control signal, and a sink transistor coupled to a current-path terminal of the protection transistor and ground, and wherein the sink transistor is configured to receive a second control signal and sink a portion of the current based on the second control signal; and a control system configured to regulate the first control signal for controlling the protection transistor, and regulate the second control signal for controlling the sink transistor and for applying a perturbation to the current, wherein the control system is configured to measure a response of the battery supply voltage based on the perturbation being applied to the current, and determine at least one parameter value of the at least one battery cell based on the response.

Aspect 19: A method of evaluating at least one battery cell, the method comprising: controlling, by a control system, a protection transistor coupled between a battery terminal of the at least one battery cell and a supply terminal of a charge/discharge circuit, wherein the protection transistor is configured to conduct a current based on a control signal; modulating, by the control system, the control signal in order to apply a perturbation to the current; and measuring, by the control system, an AC impedance of the at least one battery cell based on the perturbation being applied to the current.

Aspect 20: The method of Aspect 19, wherein measuring the AC impedance comprises: measuring an amplitude and a phase delay of a battery supply voltage in response to the perturbation being applied to the current; and calculating the AC impedance based on the amplitude and the phase delay of the battery supply voltage.

Aspect 21: The method of any of Aspects 19-20, wherein the perturbation is injected onto the current to convert the current into an AC-modulated current having an excitation frequency that is independent of a switching frequency of the charge/discharge circuit.

Aspect 22: A switched-mode power supply, comprising: a battery terminal configured to be coupled to at least one battery cell, wherein the battery terminal is configured to receive a battery supply voltage from the at least one battery cell; a DC-to-DC converter comprising at least one power switch, wherein the DC-to-DC converter is configured to use the at least one power switch to convert an input voltage to an output voltage and control a current flowing between the DC-to-DC converter and the battery terminal; a first controller configured to regulate at least one PWM control signal for controlling the at least one power switch; a protection circuit coupled between the battery terminal and a supply terminal of the DC-to-DC converter, wherein the protection circuit includes a protection transistor configured to receive a first control signal and modulate the current based on the first control signal; and a second controller configured to modulate the first control signal for controlling the protection transistor and for applying a first perturbation to the current, wherein the second controller is configured to measure an AC impedance of the at least one battery cell based on the first perturbation being applied to the current.

Aspect 23: A method of evaluating at least one battery cell, the method comprising: receiving, at a battery terminal coupled to the at least one battery cell, a battery supply voltage from the at least one battery cell; converting, by a DC-to-DC converter, an input voltage to an output voltage; controlling, by the DC-to-DC converter, a current flowing between the DC-to-DC converter and the battery terminal; controlling, by a controller, a protection transistor coupled between the battery terminal and a supply terminal of the DC-to-DC converter, wherein the protection transistor is configured to modulate the current based on a control signal; modulating, by the controller, the control signal in order to apply a perturbation to the current; and measuring, by the controller, an AC impedance of the at least one battery cell based on the perturbation being applied to the current.

Aspect 24: A system configured to perform one or more operations recited in one or more of Aspects 1-23.

Aspect 25: An apparatus comprising means for performing one or more operations recited in one or more of Aspects 1-23.

Aspect 26: A non-transitory computer-readable medium storing a set of instructions, the set of instructions comprising one or more instructions that, when executed by a device, cause the device to perform one or more operations recited in one or more of Aspects 1-23.

Aspect 27: A computer program product comprising instructions or code for executing one or more operations recited in one or more of Aspects 1-23.

The foregoing disclosure provides illustration and description, but is not intended to be exhaustive or to limit the implementations to the precise form disclosed. Modifications and variations may be made in light of the above disclosure or may be acquired from practice of the implementations.

As used herein, the term “component” is intended to be broadly construed as hardware, firmware, or a combination of hardware and software. Systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

Any of the processing components may be implemented as a central processing unit (CPU) or other processor reading and executing a software program from a non-transitory computer-readable recording medium such as a hard disk or a semiconductor memory device. For example, instructions may be executed by one or more processors, such as one or more CPUs, digital signal processors (DSPs), general-purpose microprocessors, application-specific integrated circuits (ASICs), field programmable logic arrays (FPLAs), programmable logic controller (PLC), or other equivalent integrated or discrete logic circuitry. Accordingly, the term “processor,” as used herein, refers to any of the foregoing structures or any other structure suitable for implementation of the techniques described herein. Software may be stored on a non-transitory computer-readable medium such that the non-transitory computer readable medium includes program code or a program algorithm stored thereon that, when executed, causes the processor, via a computer program, to perform the steps of a method.

A controller including hardware may also perform one or more of the techniques of this disclosure. A controller, including one or more processors, may use electrical signals and digital algorithms to perform its receptive, analytic, and control functions, which may further include corrective functions. Such hardware, software, and firmware may be implemented within the same device or within separate devices to support the various techniques described in this disclosure.

A signal processing circuit and/or a signal conditioning circuit may receive one or more signals (e.g., measurement signals) from one or more components in the form of raw measurement data and may derive, from the measurement signal, further information. “Signal conditioning,” as used herein, refers to manipulating an analog signal in such a way that the signal meets the requirements of a next stage for further processing. Signal conditioning may include converting from analog to digital (e.g., via an analog-to-digital converter), amplification, filtering, converting, biasing, range matching, isolation, and any other processes required to make a signal suitable for processing after conditioning.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a and b, a and c, b and c, and a, b, and c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A battery charging and discharging system, comprising:
a protection circuit configured to protect a charge/discharge circuit and coupled between a battery terminal of at least one battery cell and a supply terminal,
wherein the supply terminal is configured to supply the charge/discharge circuit,
wherein the protection circuit includes a protection transistor configured to receive a first control signal and conduct a current based on the first control signal; and
a first control system configured to modulate the first control signal for controlling the protection transistor and for applying a first perturbation to the current,
wherein the first control system is configured to measure an alternating current (AC) impedance of the at least one battery cell based on the first perturbation being applied to the current.

2. The battery charging and discharging system of claim 1, wherein battery terminal is configured to provide a battery supply voltage, and
wherein the first control system is configured to measure an amplitude and a phase delay of the battery supply voltage in response to the first perturbation being applied to the current, and calculate the AC impedance based on the amplitude and the phase delay of the battery supply voltage.

3. The battery charging and discharging system of claim 2, wherein the protection transistor is configured to inject the first perturbation onto the current to convert the current into an AC-modulated current, and
wherein the phase delay is a phase difference between the AC-modulated current and the battery supply voltage.

4. The battery charging and discharging system of claim 1, wherein the first control system is configured to determine a state-of-health parameter of the at least one battery cell based on the AC impedance.

5. The battery charging and discharging system of claim 1, wherein the protection transistor includes a first current-path terminal coupled to the battery terminal, and a second current-path terminal coupled to the supply terminal, and
wherein the protection transistor is configured to inject the first perturbation onto the current to convert the current into an AC-modulated current having an excitation frequency that is independent of a switching frequency of the charge/discharge circuit.

6. The battery charging and discharging system of claim 5, wherein the AC-modulated current has a multi-frequency profile comprising multiple frequencies, and
wherein the first control system is configured to measure the AC impedance of the at least one battery cell for each frequency of the multiple frequencies.

7. The battery charging and discharging system of claim 5, wherein the AC-modulated current is a single sine wave, a combination of multiple sine waves, a frequency ramp, an exponential chirp, or a pseudorandom binary sequence.

8. The battery charging and discharging system of claim 1, wherein the protection circuit includes a decoupling capacitor coupled to the supply terminal and ground, and
wherein the decoupling capacitor is configured to reduce signal components of the first perturbation entering the charge/discharge circuit.

9. The battery charging and discharging system of claim 1, wherein the charge/discharge circuit is configured to control a direction of a flow of the current between the supply terminal and the battery terminal, and
wherein, during a charging operation, the charge/discharge circuit is configured to provide the current from the supply terminal to the battery terminal as a charging current for charging the at least one battery cell, and
wherein, during a discharging operation, the charge/discharge circuit is configured to receive the current at the supply terminal from the battery terminal as a discharging current for discharging the at least one battery cell.

10. The battery charging and discharging system of claim 9, wherein the first control system is configured to apply the first perturbation to the current during the charging operation according to an electrochemical impedance spectroscopy (EIS) scheme, and
wherein the first control system is configured to determine the AC impedance based on the EIS scheme.

11. The battery charging and discharging system of claim 1, wherein the charge/discharge circuit comprises a second control system configured to control a charging and a discharging of the at least one battery cell,
wherein the first control system and the second control system are communicatively coupled, and
wherein the second control system is configured to control a timing at which the first control system is to apply the first perturbation to the current.

12. The battery charging and discharging system of claim 1, wherein the charge/discharge circuit comprises a second control system configured to control a charging and a discharging of the at least one battery cell,
wherein the first control system and the second control system are communicatively coupled,
wherein the first control system is configured to indicate, to the second control system, a timing at which the first control system is to apply the first perturbation to the current, and
wherein the second control system is configured to compensate for the first perturbation based on the timing.

13. The battery charging and discharging system of claim 1, wherein battery terminal is configured to provide a battery supply voltage,
wherein the protection circuit includes a sink transistor coupled to a current-path terminal of the protection transistor and ground,
wherein the sink transistor is configured to receive a second control signal and sink a portion of the current based on the second control signal,
wherein the first control system is configured to modulate the second control signal for controlling the sink transistor and for applying a second perturbation to the current, and
wherein the first control system is configured to measure a response of the battery supply voltage based on the second perturbation being applied to the current, and determine a parameter value of the at least one battery cell based on the response.

14. The battery charging and discharging system of claim 13, wherein the second perturbation is a current step resulting in a decaying voltage waveform of the battery supply voltage, and
wherein the first control system is configured to measure the response of the battery supply voltage by measuring a time constant of the decaying voltage waveform of the battery supply voltage.

15. The battery charging and discharging system of claim 13, wherein the first control system is configured to apply the second perturbation to the current during a discharging operation of the charge/discharge circuit according to a current interrupt (CIR) scheme,
wherein, during the discharging operation, the charge/discharge circuit is configured to receive the current at the supply terminal from the battery terminal as a discharging current for discharging the at least one battery cell, and
wherein the first control system is configured to determine the parameter value based on the CIR scheme.

16. The battery charging and discharging system of claim 1, wherein the charge/discharge circuit comprises:
a direct current (DC)-to-DC converter coupled to the supply terminal, wherein the DC-to-DC converter comprises at least one power switch and is configured to use the at least one power switch to convert an input voltage at the supply terminal to an output voltage and control a flow of the current between the supply terminal and the battery terminal; and
a second control system configured to regulate at least one pulse width modulation (PWM) control signal for controlling the at least one power switch.

17. The battery charging and discharging system of claim 16, wherein the first control system is configured to modulate the first control signal to generate the first perturbation with an excitation frequency that is independent of a switching frequency of the at least one power switch.

18. A battery charging and discharging system, comprising:
a protection circuit configured to protect a charge/discharge circuit and coupled between a battery terminal of at least one battery cell and a supply terminal,
wherein the battery terminal is configured to provide a battery supply voltage,
wherein the supply terminal is configured to supply the charge/discharge circuit,
wherein the protection circuit includes a protection transistor configured to receive a first control signal and conduct a current based on the first control signal, and a sink transistor coupled to a current-path terminal of the protection transistor and ground, and
wherein the sink transistor is configured to receive a second control signal and sink a portion of the current based on the second control signal; and
a control system configured to regulate the first control signal for controlling the protection transistor, and regulate the second control signal for controlling the sink transistor and for applying a perturbation to the current,
wherein the control system is configured to measure a response of the battery supply voltage based on the perturbation being applied to the current, and determine at least one parameter value of the at least one battery cell based on the response.

19. A method of evaluating at least one battery cell, the method comprising:
controlling, by a control system, a protection transistor coupled between a battery terminal of the at least one battery cell and a supply terminal of a charge/discharge circuit, wherein the protection transistor is configured to conduct a current based on a control signal;
modulating, by the control system, the control signal in order to apply a perturbation to the current; and
measuring, by the control system, an alternating current (AC) impedance of the at least one battery cell based on the perturbation being applied to the current.

20. The method of claim 19, wherein measuring the AC impedance comprises:
measuring an amplitude and a phase delay of a battery supply voltage in response to the perturbation being applied to the current; and
calculating the AC impedance based on the amplitude and the phase delay of the battery supply voltage.

21. The method of claim 19, wherein the perturbation is injected onto the current to convert the current into an AC-modulated current having an excitation frequency that is independent of a switching frequency of the charge/discharge circuit.
